(19) United States
(12) Patent Application Publication
(10) Pub. No.: US 2023/0309252 A1
(43) Pub. Date: Sep. 28, 2023

(54) ELECTRONIC EQUIPMENT

(71) Applicant: DELTA ELECTRONICS, INC., Taoyuan City (TW)

(72) Inventor: Chuang-Huan CHIU, Taoyuan City (TW)

(21) Appl. No.: 18/146,389

(22) Filed: Dec. 26, 2022

(30) Foreign Application Priority Data
Mar. 28, 2022 (CN) 202220680175.1

(51) Int. Cl. H05K 7/14

(52) U.S. Cl. CPC H05K 7/1417

(57) ABSTRACT

An electronic equipment includes a rack and a chassis. The rack includes two sidewalls. The sidewalls are separated from each other by a first distance. The sidewalls define a first chamber therebetween. The chassis is configured to be accommodated in the first chamber. The chassis includes a main body and at least a pair of first elastic latches. The first elastic latches are disposed on two opposite sides of the main body. Each of the first elastic sheets has an abutting surface. The abutting surfaces face away from each other and are respectively configured to at least partially abut against the corresponding sidewall. When the abutting surfaces are located outside the first chamber, the abutting surfaces are separated from each other by a second distance longer than the first distance.

### RELATED APPLICATIONS

This application claims priority to Chinese Application Serial Number 202220680175.1 filed Mar. 28, 2022, which is herein incorporated by reference.

### BACKGROUND

### Technical Field

The present disclosure relates to electronic equipment. More particularly, the present disclosure relates to electronic equipment of which a chassis is installed in a rack.

### Description of Related Art

With the improvement of living qualities nowadays, the demand of people for electronic equipment has also been increasing. Correspondingly, in order to fulfill the increasing demand of consumers, the manufacturers have been working hard to improve the electronic equipment.

Apart from enhancing the performance of electronic equipment, for example, the approach to reinforce the structure of electronic equipment to be more stable and reliable at low cost, is undoubtedly an important issue which the industry highly concerns.

### SUMMARY

A technical aspect of the present disclosure is to provide an electronic equipment, which can effectively prevent a chassis installed in a rack from loosening and thus moving out of the rack.

According to an embodiment of the present disclosure, an electronic equipment includes a rack and a chassis. The rack includes two sidewalls. The sidewalls are separated from each other by a first distance. The sidewalls define a first chamber therebetween. The chassis is configured to be accommodated in the first chamber. The chassis includes a main body and at least a pair of first elastic latches. The first elastic latches are disposed on two opposite sides of the main body. Each of the first elastic latches has an abutting surface. The abutting surfaces face away from each other and are respectively configured to at least partially abut against the corresponding sidewall. When the abutting surfaces are located outside the first chamber, the abutting surfaces are separated from each other by a second distance. The second distance is longer than the first distance.

In one or more embodiments of the present disclosure, each of the sidewalls has an edge. The edges define a first opening therebetween. The chassis is configured to penetrate through the first opening and move into the first chamber along a first direction. Each of the first elastic latches includes a first fixing portion, an abutting portion and a connecting portion. The first fixing portion is connected with a side surface of the main body. Each of the abutting surfaces is located on the corresponding abutting portion. The connecting portion is at least partially connected elastically and bendably between the first fixing portion and the abutting portion along the first direction. The connecting portion and the main body are at least partially separated from each other.

In one or more embodiments of the present disclosure, each of the connecting portions is inclined to the corresponding side surface of the main body.

In one or more embodiments of the present disclosure, each of the sidewalls has at least one first through hole. Each of the first elastic latches has a second through hole. The chassis further includes a pair of second elastic latches. The second elastic latches are disposed on two opposite sides of the main body. Each of the second elastic latches includes a second fixing portion, a moving portion and at least one hooking portion. The second fixing portion is at least partially connected between the corresponding side surface of the main body and the corresponding first fixing portion. The moving portion is elastically and bendably connected with the second fixing portion. The hooking portion is disposed on the moving portion and is configured to penetrate through the corresponding second through hole and buckle with the corresponding first through hole.

In one or more embodiments of the present disclosure, each of the first elastic latches has a third through hole. Each of the third through holes is at least partially located on the corresponding abutting portion. When the chassis is at least partially located in the first chamber and the abutting surfaces abut against the sidewalls, the abutting portions and the third through holes are at least partially exposed outside the rack.

In one or more embodiments of the present disclosure, each of the sidewalls has at least one first through hole. Each of the first elastic latches further includes at least one hooking portion. The hooking portion is disposed on the abutting portion and is configured to buckle with the corresponding first through hole.

In one or more embodiments of the present disclosure, the main body includes a housing and a plurality of isolating plates. The housing has a second opening and a second chamber communicated with the second opening along the first direction. The housing is connected between the first fixing portions along a second direction. The second direction is perpendicular to the first direction. The isolating plates are disposed inside the housing and are separated from each other along the second direction. The isolating plates respectively extend along the first direction to divide the second chamber into a plurality of subsidiary chambers. The second opening is configured to allow a plurality of electronic devices to penetrate through. The subsidiary chambers are configured to accommodate the electronic devices.

In one or more embodiments of the present disclosure, the main body further includes a pair of hollow extending structures. The hollow extending structures respectively extend along the first direction. The housing is connected between the hollow extending structures along the second direction. The first fixing portions are respectively connected with the corresponding hollow extending structure.

In one or more embodiments of the present disclosure, when the abutting surfaces abut against the sidewalls, the main body and the sidewalls are separated from each other.

In one or more embodiments of the present disclosure, when the abutting surfaces abut against the sidewalls, each of the sidewalls and the corresponding side surface of the main body are separated from each other by a gap.

According to an embodiment of the present disclosure, an electronic equipment includes a rack and a chassis. The rack includes two opposite sidewalls. The sidewalls define a first chamber therebetween. The chassis includes a main body and at least a pair of first elastic latches. The main body is configured to be accommodated in the first chamber. The first elastic latches are structurally symmetrical with each other and are disposed on two opposite sides of the main body. The first elastic latches are respectively configured to elastically abut against the corresponding sidewall when the main body is accommodated in the first chamber.

In one or more embodiments of the present disclosure, each of the sidewalls has an edge. The edges define a first opening therebetween. The chassis is configured to penetrate through the first opening and move into the first chamber along a first direction. Each of the first elastic latches includes a first fixing portion, an abutting portion and a connecting portion. The first fixing portion is connected with a side surface of the main body. The abutting portion is configured to abut against the corresponding sidewall. The connecting portion is at least partially connected elastically and bendably between the first fixing portion and the abutting portion along the first direction. The connecting portion and the main body are at least partially separated from each other.

In one or more embodiments of the present disclosure, each of the connecting portions is inclined to the corresponding side surface of the main body.

In one or more embodiments of the present disclosure, each of the sidewalls has at least one first through hole. Each of the first elastic latches has a second through hole. The chassis further includes a pair of second elastic latches. The second elastic latches are disposed on two opposite sides of the main body. Each of the second elastic latches includes a second fixing portion, a moving portion and at least one hooking portion. The second fixing portion is at least partially connected between the corresponding side surface of the main body and the corresponding first fixing portion. The moving portion is elastically and bendably connected with the second fixing portion. The hooking portion is disposed on the moving portion and is configured to penetrate through the corresponding second through hole and buckle with the corresponding first through hole.

In one or more embodiments of the present disclosure, each of the first elastic latches has a third through hole. Each of the third through holes is at least partially located on the corresponding abutting portion. When the chassis is at least partially located in the first chamber and the abutting portions abut against the sidewalls, the abutting portions and the third through holes are at least partially exposed outside the rack.

In one or more embodiments of the present disclosure, each of the sidewalls has at least one first through hole. Each of the first elastic latches further includes at least one hooking portion. The hooking portion is disposed on the abutting portion and is configured to buckle with the corresponding first through hole.

In one or more embodiments of the present disclosure, the main body includes a housing and a plurality of isolating plates. The housing has a second opening and a second chamber communicated with the second opening along the first direction. The housing is connected between the first fixing portions along a second direction. The second direction is perpendicular to the first direction. The isolating plates are disposed inside the housing and are separated from each other along the second direction. The isolating plates respectively extend along the first direction to divide the second chamber into a plurality of subsidiary chambers. The second opening is configured to allow a plurality of power supplying devices to penetrate through. The subsidiary chambers are configured to accommodate the power supplying devices.

In one or more embodiments of the present disclosure, the main body further includes a pair of hollow extending structures. The hollow extending structures respectively extend along the first direction. The housing is connected between the hollow extending structures along the second direction. The first fixing portions are respectively connected with the corresponding hollow extending structure.

In one or more embodiments of the present disclosure, when the abutting portions abut against the sidewalls, the main body and the sidewalls are separated from each other.

In one or more embodiments of the present disclosure, when the abutting portions abut against the sidewalls, each of the sidewalls and the corresponding side surface of the main body are separated from each other by a gap.

The above-mentioned embodiments of the present disclosure have at least the following advantages:

(1) When the chassis is installed in the first chamber of the rack, the first elastic latches of the chassis elastically deform as compressed by the sidewalls, such that the abutting portions the first elastic latches elastically move towards the main body relative to the first fixing portions. In this way, each of the first elastic latches can exert a corresponding amount of elastic force on the main body, such that the main body of the chassis can remain to be separated from the sidewalls of the rack. In other words, each of the sidewalls of the rack and the corresponding side surface of the main body are separated from each other by a gap. Thus, in the process to install the chassis in the rack, the chassis is effectively avoided from shifting and the main body is avoided from becoming too close to one of the sidewalls of the rack, which may otherwise cause that the hooking portion of at least one of the second elastic latches cannot be buckled to the corresponding first through hole of the rack and thus the chassis may loosen and move out of the rack.

(2) Since the first elastic latches are disposed on two opposite sides of the main body, and are configured to elastically abut against between the main body and the sidewalls of the rack, the first elastic latches can facilitate the centering of the chassis in the first chamber of the rack in a simple and easy manner.

### BRIEF DESCRIPTION OF THE DRAWINGS

The disclosure can be more fully understood by reading the following detailed description of the embodiments, with reference made to the accompanying drawings as follows:

FIG. 1 is a schematic view of an electronic equipment according to an embodiment of the present disclosure, in which the chassis is located outside the rack;

FIG. 2 is a partially enlarged view of the chassis of FIG. 1;

FIG. 3 is a partially exploded view of the chassis of FIG. 2;

FIG. 4 is a partially enlarged top view of the first elastic latch, the second elastic latch and the main body of FIGS. 2-3;

FIG. 5 is a partially sectional top view of the chassis of FIG. 1 partially located in the rack;

FIG. 6 is a partially sectional top view of the chassis of FIG. 1 located in the rack, in which the first elastic latches of the chassis abut against the sidewalls of the rack;

FIG. 7 is a partially enlarged side view of an electronic equipment according to another embodiment of the present disclosure, in which the chassis is already installed in the rack;

FIG. 8 is a schematic view of a first elastic latch according to a further embodiment of the present disclosure; and

FIG. 9 is a partially schematic view of a chassis according to another embodiment of the present disclosure.

### DETAILED DESCRIPTION

Drawings will be used below to disclose embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meanings as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

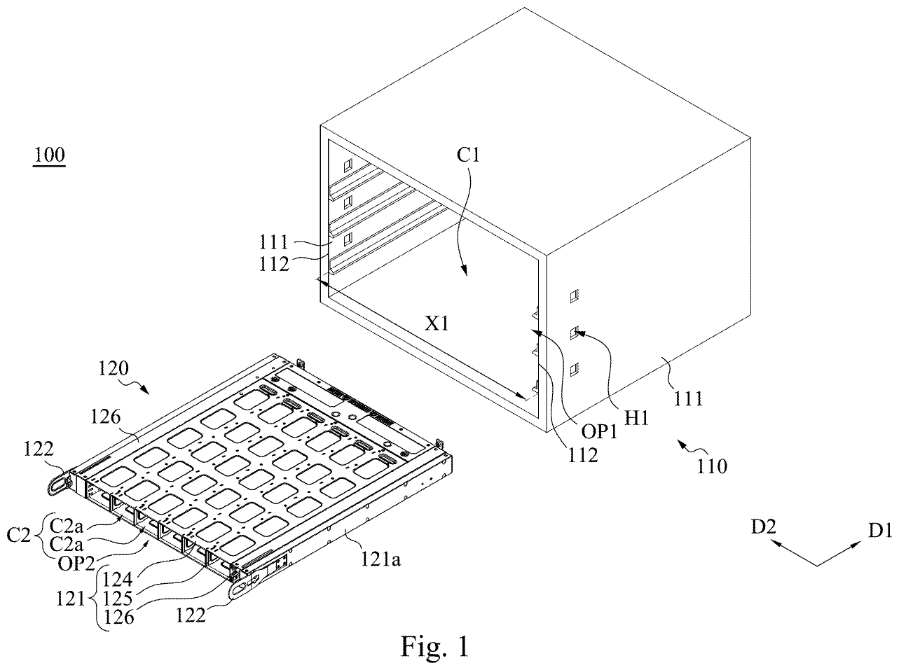

Reference is made to FIG. 1. FIG. 1 is a schematic view of an electronic equipment 100 according to an embodiment of the present disclosure, in which the chassis 120 is located outside the rack 110. In this embodiment, as shown in FIG. 1, an electronic equipment 100 includes a rack 110 and a chassis 120. The rack 110 includes two sidewalls 111. The sidewalls 111 are separated from each other by a first distance X1. The sidewalls 111 define a first chamber C1 therebetween. The chassis 120 includes a main body 121 and at least a pair of first elastic latches 122. The first elastic latches 122 are structurally symmetrical with each other and are disposed on two opposite sides of the main body 121. Each of the sidewalls 111 of the rack 110 has an edge 112. The edges 112 define a first opening OP1 therebetween. The chassis 120 is configured to penetrate through the first opening OP1 of the rack 110 and move into the first chamber C1 along a first direction D1, such that the chassis 120 is accommodated in the first chamber C1. In practical applications, the rack 110 can accommodate a plurality of chassis 120 at the same time. However, please be noted that, the rack 110 shown in FIG. 1 is only illustrative and is not supposed to limit the quantity of the chassis 120 to be accommodated in the rack 110.

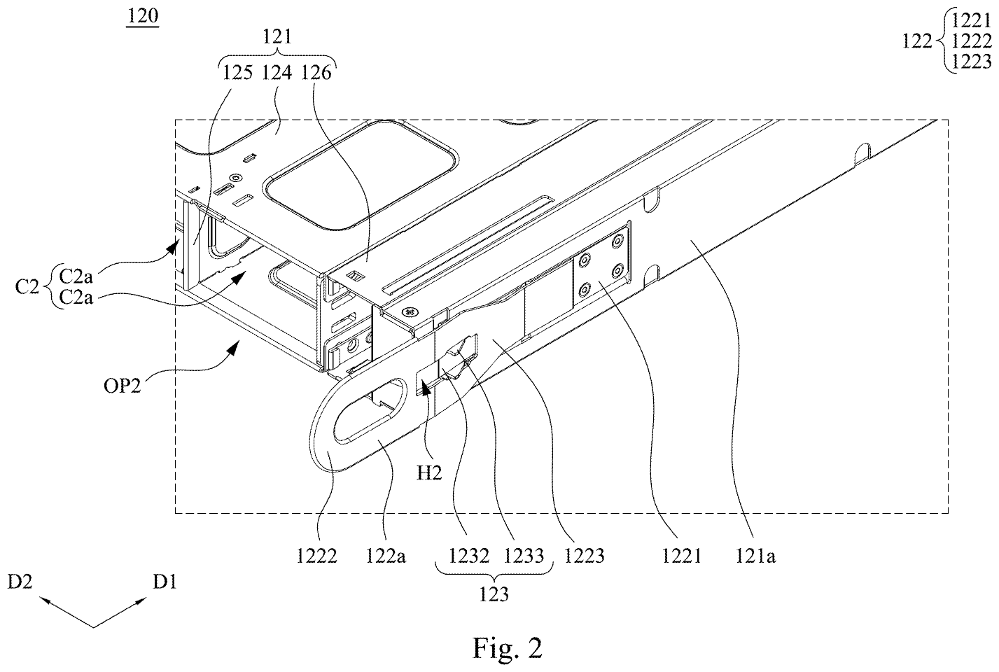

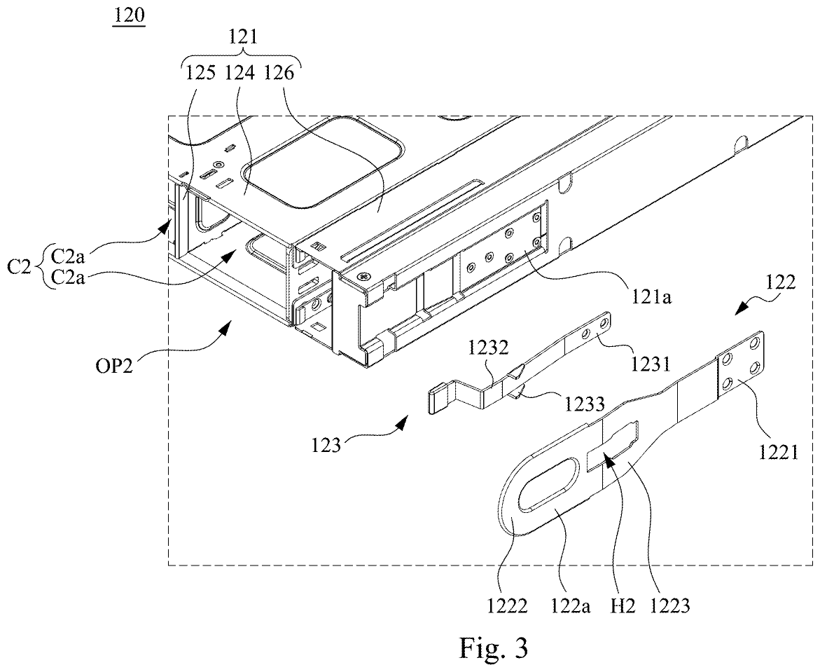

Reference is made to FIGS. 2-3. FIG. 2 is a partially enlarged view of the chassis 120 of FIG. 1. FIG. 3 is a partially exploded view of the chassis 120 of FIG. 2. In this embodiment, as shown in FIGS. 2-3, each of the first elastic latches 122 has an abutting surface 122a. The respective abutting surfaces 122a of the two first elastic latches 122 face away from each other and are respectively configured to at least partially abut against the corresponding sidewall 111 (please see FIG. 1 for the sidewalls 111) of the rack 110. To be specific, each of the first elastic latches 122 of the chassis 120 includes a first fixing portion 1221, an abutting portion 1222 and a connecting portion 1223. The first fixing portion 1221 of each of the first elastic latches 122 is connected with a side surface 121a of the main body 121. The abutting surface 122a is located on the corresponding abutting portion 1222. It is worth to note that, the connecting portion 1223 of each of the first elastic latches 122 is at least partially connected elastically and bendably between the first fixing portion 1221 and the abutting portion 1222 along the first direction D1.

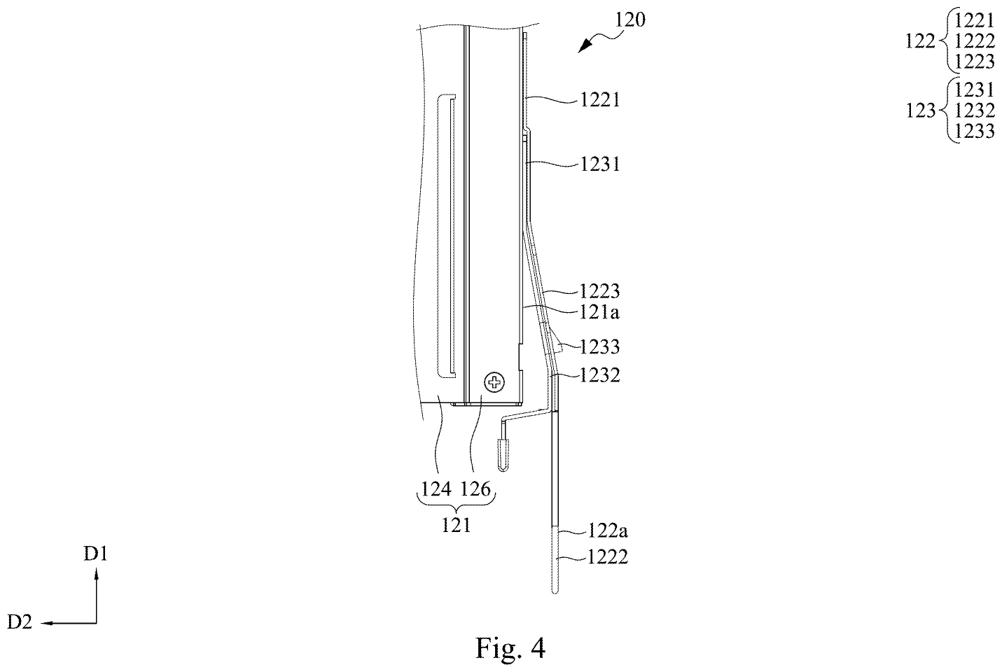

Reference is made to FIG. 4. FIG. 4 is a partially enlarged top view of the first elastic latch 122, the second elastic latch 123 and the main body 121 of FIGS. 2-3. In this embodiment, as shown in FIG. 4, the connecting portion 1223 of each of the first elastic latches 122 and the main body 121 are at least partially separated from each other, and each of the connecting portions 1223 is inclined to the corresponding side surface 121a of the main body 121. Moreover, the abutting surface 122a located on the abutting portion 1222 is farther away from the side surface 121a than the corresponding connecting portion 1223 from the side surface 121a along the normal direction of the side surface 121a.

Furthermore, as shown in FIGS. 2-4, the chassis 120 further includes a pair of second elastic latches 123. The second elastic latches 123 are disposed on two opposite sides of the main body 121. To be specific, each of the second elastic latches 123 includes a second fixing portion 1231, a moving portion 1232 and at least one hooking portion 1233. The second fixing portion 1231 of each of the second elastic latches 123 is at least partially connected between the corresponding side surface 121a of the main body 121 and the corresponding first fixing portion 1221. The moving portion 1232 is elastically and bendably connected with the second fixing portion 1231. The hooking portion 1233 is disposed on the moving portion 1232. Each of the first elastic latches 122 has a second through hole H2. The second through hole H2 of each of the first elastic latches 122 is configured to allow the hooking portion 1233 of the corresponding second elastic latch 123 to penetrate through. According to the actual situation, the second through hole H2 can be located either on the first fixing portion 1221, the abutting portion 1222 or the connecting portion 1223. On the other hand, the second through hole H2 may span across the abutting portion 1222 and the connecting portion 1223, across the connecting portion 1223 and the first fixing portion 1221, or across the first fixing portion 1221, the abutting portion 1222 and the connecting portion 1223. For example, as shown in FIGS. 2-3, the second through hole H2 spans across the abutting portion 1222 and the connecting portion 1223. However, this does not intend to limit the present disclosure.

On the other hand, as shown in FIGS. 1-3, the main body 121 of the chassis 120 includes a housing 124 and a plurality of isolating plates 125. The housing 124 of the main body 121 has a second opening OP2 and a second chamber C2 communicated with the second opening OP2 along the first direction D1. The housing 124 is connected between the first fixing portions 1221 of the first elastic latches 122 along a second direction D2. The second direction D2 is perpendicular to the first direction D1. The isolating plates 125 of the main body 121 are disposed inside the housing 124 and are separated from each other along the second direction D2. The isolating plates 125 respectively extend along the first direction D1 to divide the second chamber C2 into a plurality of subsidiary chambers C2a. The second opening OP2 is configured to allow a plurality of electronic devices (not shown) to penetrate through. The subsidiary chambers C2a are configured to accommodate the electronic devices. In practical applications, for example, the electronic devices can be power supplying devices. However, this does not intend to limit the present disclosure.

Furthermore, as shown in FIGS. 1-4, the main body 121 of the chassis 120 further includes a pair of hollow extending structures 126. The hollow extending structures 126 respectively extend along the first direction D1. The housing 124 is connected between the hollow extending structures 126 along the second direction D2. In this embodiment, the first fixing portions 1221 of the first elastic latches 122 are respectively connected with the corresponding hollow extending structure 126. As the hollow extending structures 126 are connected to two opposite sides of the housing 124, a user can correspondingly adjust the overall width of the chassis 120 with respect to the first distance X1 separated between the sidewalls 111 of the rack 110, such that the dimensions of the chassis 120 is suitable to be accommodated in the rack 110.

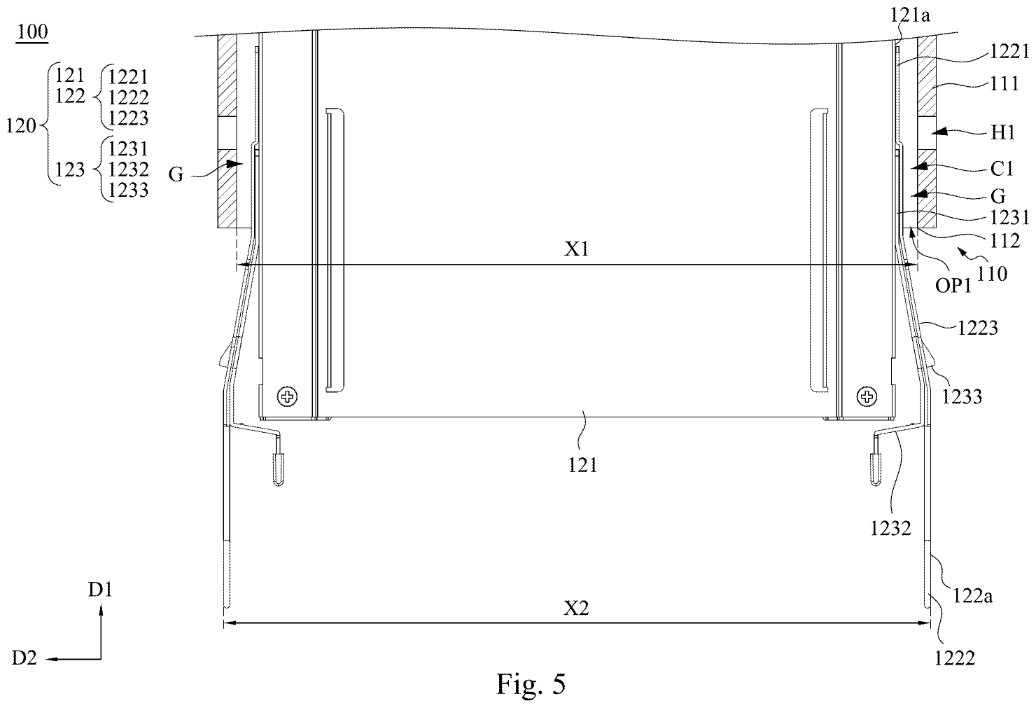

Reference is made to FIG. 5. FIG. 5 is a partially sectional top view of the chassis 120 of FIG. 1 partially located in the rack 110. As shown in FIG. 5, the chassis 120 is being prepared to be installed in the first chamber C1 of the rack 110 or being pulled out from the first chamber C1 of the rack 110, while the abutting surfaces 122a of the first elastic latches 122 are away from the sidewalls 111 of the rack 110 and located outside the first chamber C1. In this embodiment, it is worth to note that, when the abutting surfaces 122a of the first elastic latches 122 are away from the sidewalls 111 of the rack 110 and located outside the first chamber C1, the abutting surfaces 122a are at least partially separated from each other by a second distance X2. The second distance X2 is longer than the first distance X1 between the sidewalls 111.

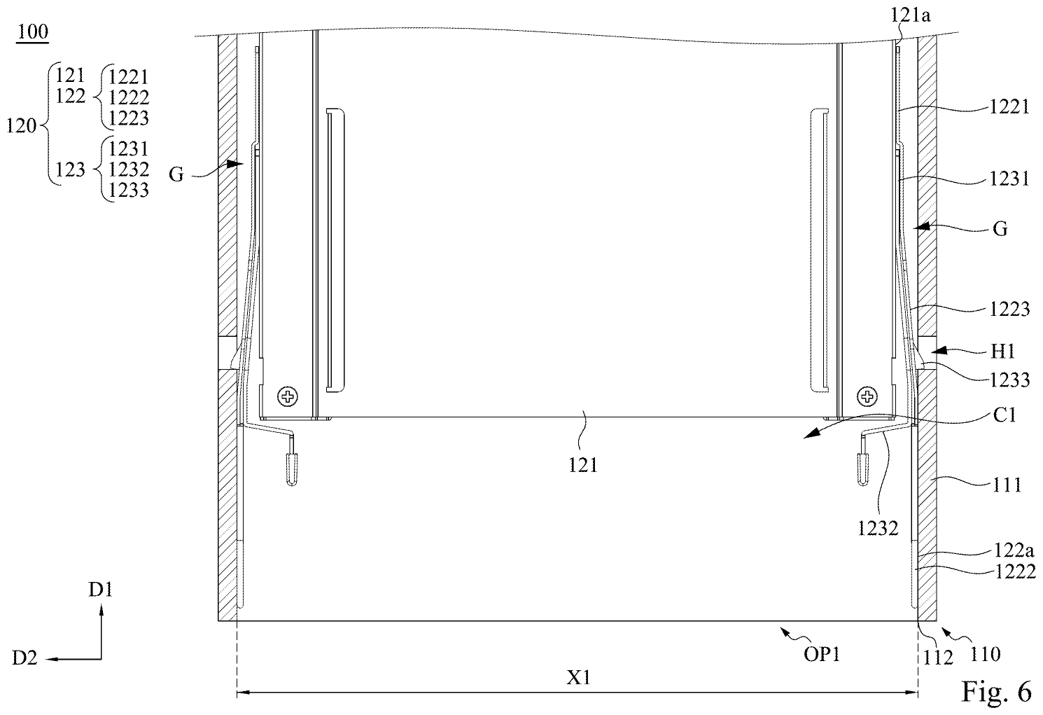

Reference is made to FIG. 6. FIG. 6 is a partially sectional top view of the chassis 120 of FIG. 1 located in the rack 110, in which the first elastic latches 122 of the chassis 120 abut against the sidewalls 111 of the rack 110. As shown in FIG. 6, the chassis 120 is already installed in the first chamber C1 of the rack 110, and the abutting surfaces 122a of the first elastic latches 122 abut against the sidewalls 111 of the rack 110. In addition, as shown in FIGS. 1, 5-6, each of the sidewalls 111 of the rack 110 has at least one first through hole H1. In this embodiment, when the chassis 120 is installed in the first chamber C1 of the rack 110 and the first elastic latches 122 abut against the sidewalls 111 of the rack 110, the hooking portion 1233 of each of the second elastic latches 123 buckles with the corresponding first through hole H1, in order to prevent the chassis 120 from loosening and thus moving out of the rack 110.

It is worth to note that, as mentioned above, when the abutting surfaces 122a of the first elastic latches 122 are located outside the first chamber C1, the second distance X2 between the abutting surfaces 122a is longer than the first distance X1 between the sidewalls 111, while the connecting portion 1223 of each of the first elastic latches 122 is at least partially connected elastically and bendably between the first fixing portion 1221 and the abutting portion 1222 along the first direction D1. As a result, when the chassis 120 is installed in the first chamber C1 of the rack 110, the first elastic latches 122 of the chassis 120 elastically deform as compressed by the sidewalls 111, such that the abutting portions 1222 the first elastic latches 122 elastically move towards the main body 121 relative to the first fixing portions 1221. In this way, each of the first elastic latches 122 can exert a corresponding amount of elastic force on the main body 121, such that the main body 121 of the chassis 120 can remain to be separated from the sidewalls 111 of the rack 110. In other words, each of the sidewalls 111 of the rack 110 and the corresponding side surface 121a of the main body 121 are separated from each other by a gap G. Thus, in the process to install the chassis 120 in the rack 110, the chassis 120 is effectively avoided from shifting and the main body 121 is avoided from becoming too close to one of the sidewalls 111 of the rack 110, which may otherwise cause that the hooking portion 1233 of at least one of the second elastic latches 123 cannot be buckled to the corresponding first through hole H1 of the rack 110 and thus the chassis 120 may loosen and move out of the rack 110. In other words, since the first elastic latches 122 are disposed on two opposite sides of the main body 121, and are configured to elastically abut against between the main body 121 and the sidewalls 111 of the rack 110, the first elastic latches 122 can facilitate the centering of the chassis 120 in the first chamber C1 of the rack 110 in a simple and easy manner.

Furthermore, as shown in FIG. 6, when the first elastic latches 122 of the chassis 120 abut against the sidewalls 111 of the rack 110, the connecting portion 1223 of each of the first elastic latches 122 is still inclined to the corresponding side surface 121a of main body 121 and is at least partially separated from the main body 121. In this way, when the chassis 120 is accommodated in the rack 110, each of the first elastic latches 122 of the chassis 120 can keep exerting a corresponding amount of elastic force on the main body 121, in order to maintain the gap G separated between each of the side surfaces 121a of the main body 121 and the corresponding sidewall 111 of the rack 110, which thus facilitates the centering of the chassis 120 in the first chamber C1 of the rack 110.

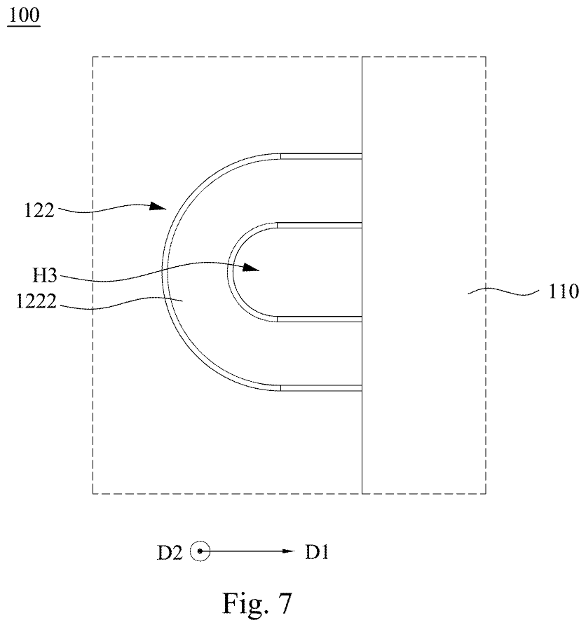

Reference is made to FIG. 7. FIG. 7 is a partially enlarged side view of an electronic equipment 100 according to another embodiment of the present disclosure, in which the chassis 120 is already installed in the rack 110. In this embodiment, as shown in FIG. 7, each of the first elastic latches 122 has a third through hole H3. Each of the third through holes H3 is at least partially located on the corresponding abutting portion 1222. After the chassis 120 (please see FIGS. 1-2 for the complete chassis 120) is already installed in the rack 110, i.e., the chassis 120 is at least partially accommodated in the first chamber C1 (please see FIG. 1) of the rack 110 and the abutting surfaces 122a of the first elastic latches 122 abut against the sidewalls 111 of the rack 110, the abutting portions 1222 and the third through holes H3 of the first elastic latches 122 are at least partially exposed outside the rack 110. In this way, the abutting portion 1222 of each of the first elastic latches 122 can be used as a handle. For example, a user can insert his/her fingers through the third through holes H3 located on the abutting portions 1222 and pull the chassis 120 out of the rack 110.

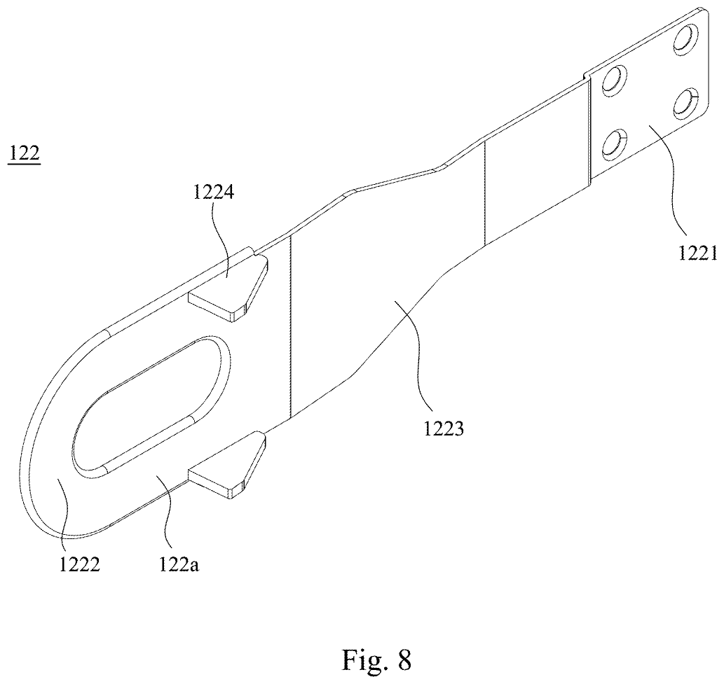

Reference is made to FIG. 8. FIG. 8 is a schematic view of a first elastic latch 122 according to a further embodiment of the present disclosure. In this embodiment, the chassis 120 does not include any of the second elastic latches 123 as mentioned above. As shown in FIG. 8, each of the first elastic latches 122 of the chassis 120 further includes at least one hooking portion 1224. The hooking portion 1224 of the first elastic latch 122 is disposed on the abutting portion 1222 and is configured to buckle with the corresponding first through hole H1 of the rack 110 when the chassis 120 is accommodated in the rack 110, in order to prevent the chassis 120 from loosening and thus moving out of the rack 110. In practical applications, the first fixing portion 1221, the abutting portion 1222, the connecting portion 1223 and the hooking portion 1224 can be of an integrally-formed structure.

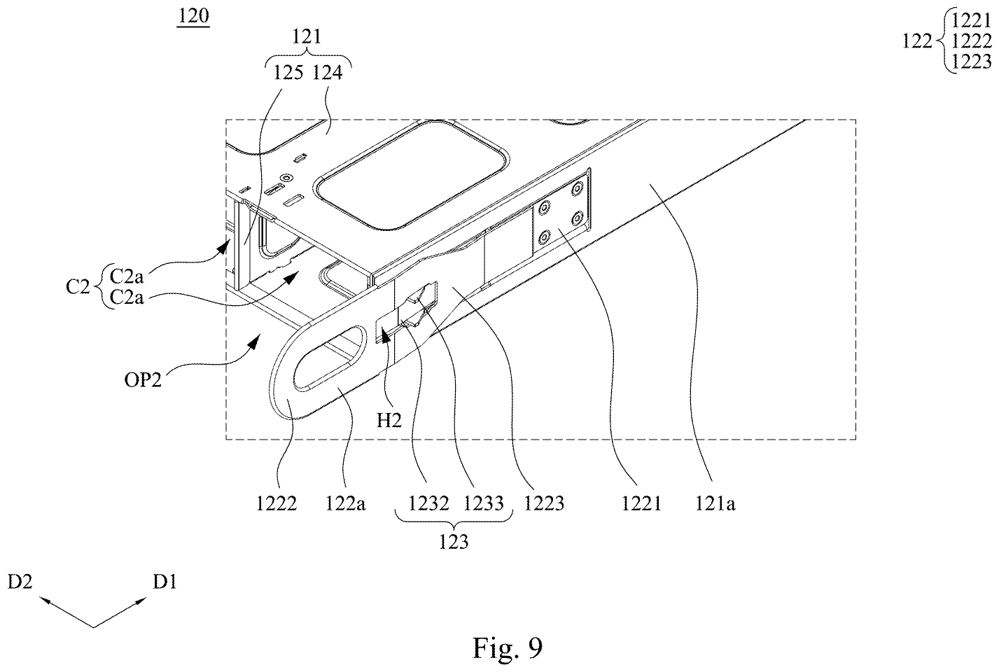

Reference is made to FIG. 9. FIG. 9 is a partially schematic view of a chassis 120 according to another embodiment of the present disclosure. In this embodiment, as shown in FIG. 9, the main body 121 of the chassis 120 does not include any of the hollow extending structures 126 as mentioned above, and the first fixing portions 1221 of the first elastic latches 122 are directly connected to the housing 124.

In conclusion, the aforementioned embodiments of the present disclosure have at least the following advantages:

(1) When the chassis is installed in the first chamber of the rack, the first elastic latches of the chassis elastically deform as compressed by the sidewalls, such that the abutting portions the first elastic latches elastically move towards the main body relative to the first fixing portions. In this way, each of the first elastic latches can exert a corresponding amount of elastic force on the main body, such that the main body of the chassis can remain to be separated from the sidewalls of the rack. In other words, each of the sidewalls of the rack and the corresponding side surface of the main body are separated from each other by a gap. Thus, in the process to install the chassis in the rack, the chassis is effectively avoided from shifting and the main body is avoided from becoming too close to one of the sidewalls of the rack, which may otherwise cause that the hooking portion of at least one of the second elastic latches cannot be buckled to the corresponding first through hole of the rack and thus the chassis may loosen and move out of the rack.

(2) Since the first elastic latches are disposed on two opposite sides of the main body, and are configured to elastically abut against between the main body and the sidewalls of the rack, the first elastic latches can facilitate the centering of the chassis in the first chamber of the rack in a simple and easy manner.

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

What is claimed is:

1. An electronic equipment, comprising:
a rack comprising two sidewalls separated from each other by a first distance, the sidewalls defining a first chamber therebetween; and
a chassis configured to be accommodated in the first chamber, the chassis comprising:
a main body; and
at least a pair of first elastic latches disposed on two opposite sides of the main body, each of the first elastic latches having an abutting surface, the abutting surfaces facing away from each other and being respectively configured to at least partially abut against the corresponding sidewall,
wherein when the abutting surfaces are located outside the first chamber, the abutting surfaces are separated from each other by a second distance longer than the first distance.

2. The electronic equipment of claim 1, wherein each of the sidewalls has an edge, the edges define a first opening therebetween, the chassis is configured to penetrate through the first opening and move into the first chamber along a first direction, each of the first elastic latches comprises:
a first fixing portion connected with a side surface of the main body;
an abutting portion, each of the abutting surfaces is located on the corresponding abutting portion; and
a connecting portion at least partially connected elastically and bendably between the first fixing portion and the abutting portion along the first direction, the connecting portion and the main body are at least partially separated from each other.

3. The electronic equipment of claim 2, wherein each of the connecting portions is inclined to the corresponding side surface of the main body.

4. The electronic equipment of claim 2, wherein each of the sidewalls has at least one first through hole, each of the first elastic latches has a second through hole, the chassis further comprises a pair of second elastic latches disposed on two opposite sides of the main body, each of the second elastic latches comprises:
a second fixing portion at least partially connected between the corresponding side surface of the main body and the corresponding first fixing portion;
a moving portion elastically and bendably connected with the second fixing portion; and
at least one hooking portion disposed on the moving portion and configured to penetrate through the corresponding second through hole and buckle with the corresponding first through hole.

5. The electronic equipment of claim 2, wherein each of the first elastic latches has a third through hole at least partially located on the corresponding abutting portion, when the chassis is at least partially located in the first chamber and the abutting surfaces abut against the sidewalls, the abutting portions and the third through holes are at least partially exposed outside the rack.

6. The electronic equipment of claim 2, wherein each of the sidewalls has at least one first through hole, each of the first elastic latches further comprises:
at least one hooking portion disposed on the abutting portion and configured to buckle with the corresponding first through hole.

7. The electronic equipment of claim 2, wherein the main body comprises:
a housing having a second opening and a second chamber communicated with the second opening along the first direction, the housing is connected between the first fixing portions along a second direction perpendicular to the first direction; and
a plurality of isolating plates disposed inside the housing and separated from each other along the second direction, the isolating plates respectively extend along the first direction to divide the second chamber into a plurality of subsidiary chambers, the second opening is configured to allow a plurality of electronic devices to penetrate through, the subsidiary chambers are configured to accommodate the electronic devices.

8. The electronic equipment of claim 7, wherein the main body further comprises:
a pair of hollow extending structures respectively extending along the first direction, the housing is connected between the hollow extending structures along the second direction, the first fixing portions are respectively connected with the corresponding hollow extending structure.

9. The electronic equipment of claim 1, wherein when the abutting surfaces abut against the sidewalls, the main body and the sidewalls are separated from each other.

10. The electronic equipment of claim 1, wherein when the abutting surfaces abut against the sidewalls, each of the sidewalls and the corresponding side surface of the main body are separated from each other by a gap.

11. An electronic equipment, comprising:
a rack comprising two opposite sidewalls defining a first chamber therebetween; and
a chassis, comprising:
a main body configured to be accommodated in the first chamber; and
at least a pair of first elastic latches structurally symmetrical with each other and disposed on two opposite sides of the main body, the first elastic latches being respectively configured to elastically abut against the corresponding sidewall when the main body is accommodated in the first chamber.

12. The electronic equipment of claim 11, wherein each of the sidewalls has an edge, the edges define a first opening therebetween, the chassis is configured to penetrate through the first opening and move into the first chamber along a first direction, each of the first elastic latches comprises:
a first fixing portion connected with a side surface of the main body;
an abutting portion configured to abut against the corresponding sidewall; and
a connecting portion at least partially connected elastically and bendably between the first fixing portion and the abutting portion along the first direction, the connecting portion and the main body are at least partially separated from each other.

13. The electronic equipment of claim 12, wherein each of the connecting portions is inclined to the corresponding side surface of the main body.

14. The electronic equipment of claim 12, wherein each of the sidewalls has at least one first through hole, each of the first elastic latches has a second through hole, the chassis further comprises a pair of second elastic latches disposed on two opposite sides of the main body, each of the second elastic latches comprises:
a second fixing portion at least partially connected between the corresponding side surface of the main body and the corresponding first fixing portion;
a moving portion elastically and bendably connected with the second fixing portion; and
at least one hooking portion disposed on the moving portion and configured to penetrate through the corresponding second through hole and buckle with the corresponding first through hole.

15. The electronic equipment of claim 12, wherein each of the first elastic latches has a third through hole at least partially located on the corresponding abutting portion, when the chassis is at least partially located in the first chamber and the abutting portions abut against the sidewalls, the abutting portions and the third through holes are at least partially exposed outside the rack.

16. The electronic equipment of claim 12, wherein each of the sidewalls has at least one first through hole, each of the first elastic latches further comprises:
at least one hooking portion disposed on the abutting portion and configured to buckle with the corresponding first through hole.

17. The electronic equipment of claim 12, wherein the main body comprises:
a housing having a second opening and a second chamber communicated with the second opening along the first direction, the housing is connected between the first fixing portions along a second direction perpendicular to the first direction; and
a plurality of isolating plates disposed inside the housing and separated from each other along the second direction, the isolating plates respectively extend along the first direction to divide the second chamber into a plurality of subsidiary chambers, the second opening is configured to allow a plurality of power supplying devices to penetrate through, the subsidiary chambers are configured to accommodate the power supplying devices.

18. The electronic equipment of claim 17, wherein the main body further comprises:
a pair of hollow extending structures respectively extending along the first direction, the housing is connected between the hollow extending structures along the second direction, the first fixing portions are respectively connected with the corresponding hollow extending structure.

19. The electronic equipment of claim 11, wherein when the abutting portions abut against the sidewalls, the main body and the sidewalls are separated from each other.

20. The electronic equipment of claim 11, wherein when the abutting portions abut against the sidewalls, each of the sidewalls and the corresponding side surface of the main body are separated from each other by a gap.
